(19) United States
(12) Patent Application Publication
(10) Pub. No.: US 2007/0253039 A1
(43) Pub. Date: Nov. 1, 2007

(54) Image processing apparatus

(75) Inventor: Norimasa Ariga, Izunokuni-shi (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 11/412,972

(22) Filed: Apr. 28, 2006

(51) Int. Cl. G03F 3/08

(52) U.S. Cl. 358/518; 358/1.9

(57) ABSTRACT

Color components are converted into full colors to be output. An achromatic color among the color components is converted into black. The achromatic color among the color components is converted into a mixed color of two colors including black and another color to be output. One of the conversion outputs is selected.

### BACKGROUND OF THE INVENTION

1. Field of the Invention

The present invention relates to an image processing apparatus which performs image processing for 2-color printing an image with, e.g., black and another color.

2. Description of the Related Art

As an image forming apparatus, for example, a digital copying machine or the like is available. Such an image forming apparatus performs 2-color printing. That is, the digital data amount of full-color printing is four times as large as that of a monochrome printing. In the full-color printing, there is a possibility of consuming color materials whose amount is larger by about 2.5 times at maximum because of a limit of an actual printer. The consumption amount of a color material such as toner should preferably be reduced. Accordingly, the number of color materials has been limited to two to perform 2-color printing.

The method of 2-color printing is as follows. A photoelectric transducer such as a color CCD reads a color original, and outputs a color image signal. A black component is separated from the color image signal. The separated black is printed by a black color material. Each color other than black is printed by another one-color material. For example, a black character is printed by a black color material. A portion of the other color is printed by one color other than black. By such-2-color printing, a document in which a noteworthy portion has a color character is copied and printed by a smaller color material amount.

A 2-color printing technology is disclosed in Jpn. Pat. Appln. KOKAI Publications No. 8-84268. Jpn. Pat. Appln. KOKAI Publication No. 8-84268 discloses the technology which detects hue data and saturation data based on color image data, generates concentration data based on the hue and saturation data, and separates the color image data into two colors based on the concentration data.

### BRIEF SUMMARY OF THE INVENTION

In accordance with a main aspect of the present invention, an image processing apparatus includes a first color converting section which converts a plurality of color components into full colors, a second color converting section which converts an achromatic color among the plurality of color components into black and other colors into one designated color, a third color converting section which converts the achromatic color among the plurality of color components into a mixed color of two colors including black and another color, and a selecting section which selects one from conversion outputs of the first to third color converting sections.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram showing an image forming apparatus to which an image processing apparatus of a first embodiment of the present invention is applied;

FIG. 2 is a block diagram of the image processing apparatus of the image forming apparatus;

FIG. 3 is a block diagram showing a second color converting section of the image forming apparatus;

FIG. 4 is a block diagram showing a third color converting section of the image forming apparatus;

FIG. 5 is a block diagram showing an image forming apparatus to which an image processing apparatus of a second embodiment of the present invention is applied;

FIG. 6 is a diagram of the image processing apparatus of the image forming apparatus;

FIG. 7 is a block diagram showing an image forming apparatus to which an image processing apparatus of a third embodiment of the present invention is applied;

FIG. 8 is a block diagram of the image processing apparatus of the image forming apparatus;

FIG. 9 is a block diagram showing a second color converting section of the image forming apparatus;

FIG. 10 is a block diagram showing a third color converting section of the image forming apparatus; and

FIG. 11 is a block diagram showing a modified example of the third color converting section of the image forming apparatus.

### DETAILED DESCRIPTION OF THE INVENTION

A first embodiment of the present invention will be described below in detail with reference to the accompanying drawings.

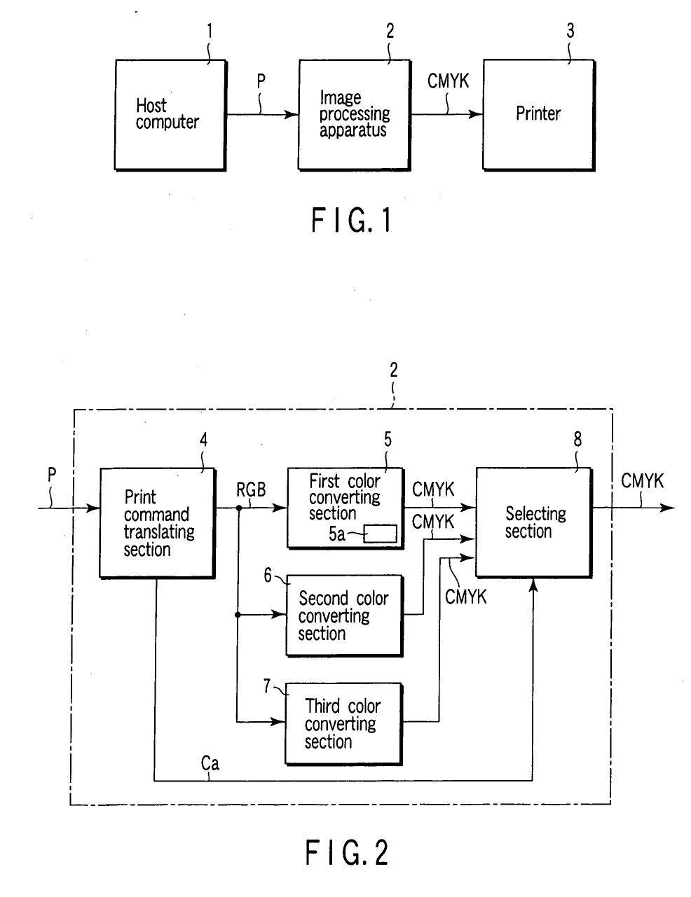

FIG. 1 is a block diagram of an image forming apparatus. The image forming apparatus includes a host computer 1, an image processing apparatus 2, and a printer 3. The host computer 1 converts a printing output of a desired image into a format of a print command P, and issues this print command P to the image processing apparatus 2. The print command P is described in page description language. In the print command P, information regarding full-color printing, 2-color printing of a character or a line drawing, bit image printing of a natural image, or the like is written.

The image processing apparatus 2 performs image processing for receiving a print command P issued from the host computer 1 to convert it into color information of an image to be printed and output from the printer 3, i.e., each color material amount of cyan (C), magenta (M), yellow (Y), and black (K). The printer 3 performs printing in an image forming medium based on each color material amount of CMYK.

FIG. 2 is a block diagram of the image processing apparatus 2. A print command translating section 4 breaks down a plurality of color components, e.g., three color components, into red (R), green (G) and blue (B) to generate image data based on the print command P issued from the host computer 1. The print command translating section 4 translates printing contents based on information written in the print command P. In other words, the print command translating section 4 generates image data from a page description language of the print command P, and translates a pixel of the image data to be full-color printing, simple 2-color printing, or natural image 2-color printing. For example, in certain printing, a full surface may be full-color printing. In another printing, a character or a graphic line drawing may be simple 2-color printing, and a natural image may be natural image 2-color printing. The print command translating section 4 outputs a switching signal Ca indicating a result of the translation.

A first color converting section 5 converts color components RGB of the pixel of the image data generated by the print command translating section 4 into full colors CMYK. The first color converting section 5 has a table 5a for conversion from RGB into CMYK. In the conversion table 5a, table values are stored to convert RGB into CMYK. The first color converting section 5 reads table values from the conversion table 5a in accordance with RGB, and performs interpolation calculation of the table values to obtain CMYK.

A second color converting section 6 converts the pixel of the image data into two colors: K and one designated color other than an achromatic color, e.g., C, M or Y. The second color converting section 6 converts an achromatic color (gray) of the image data into K.

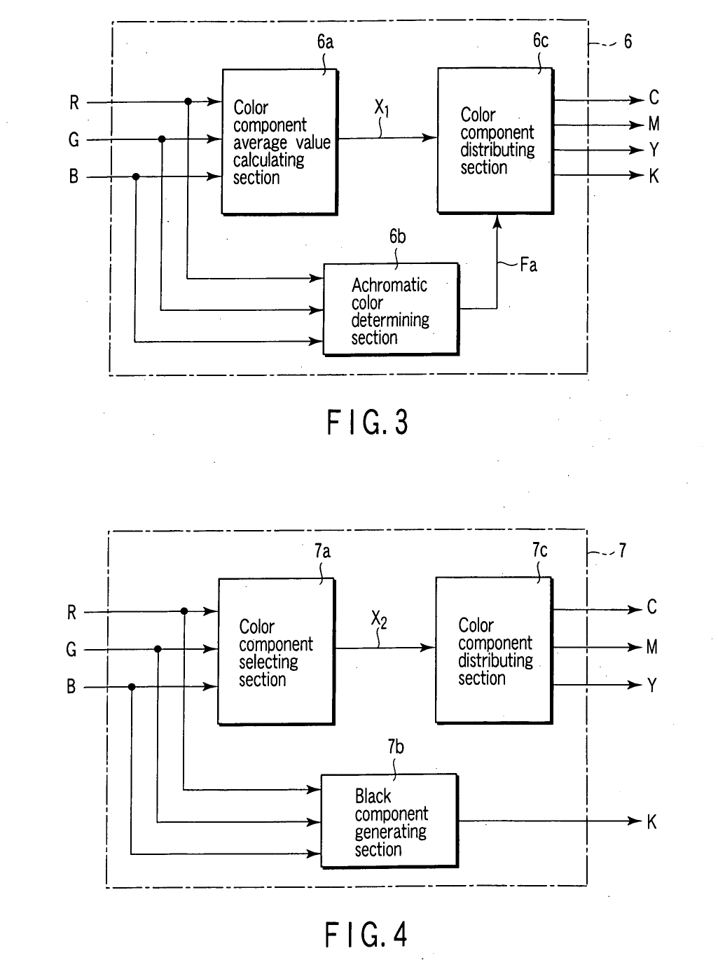

FIG. 3 is a block diagram of the second color converting section 6. The second color converting section 6 includes a color component average value calculating section 6a, an achromatic color determining section 6b, and a color component distributing section 6c.

The color component average value calculating section 6a calculates an average value X₁ of the color components RGB.

The achromatic color determining section 6b determines an achromatic color based on equality of the values of the color components RGB, and outputs a result Fa of the determination. However, considering inclusion of errors in the values of the color components RGB, the achromatic color determining section 6b determines an achromatic color if a difference between maximum and minimum values of the color components RGB is within a certain predetermined range.

That is, as long as the RGB values can be in a range of “0 to 255”, black is determined when a difference between the maximum and minimum values of the input RGB color components is at least equal to or more than 1. A threshold value of the difference between the maximum and minimum values may be changed in accordance with the average value of the input RGB.

The black determination can also be made by converting the values of the RGB color components into CIELAB values. For example, when the input RGB are sRGB color space values to be set in the range of “0 to 255”, a a* value, a b* value can be obtained as follows:

R′=R/255

G′=G/255

B′=B/255

if R′, G′, B′<=0.04045
R″=R′/12.92
G″=G′/12.92
B″=B′/12.92

else
R″=[(R′+0.055)/1.055] ˆ2.4
G″=[(G′+0.055)/1.055] ˆ2.4
B″=[(B′+0.055)/1.055] ˆ2.4

X=0.4124*R″+0.3576*G″+0.1805*B″

Y=0.2126*R″+0.7152*G″+0.0722*B″

Z=0.0193*R″*0.1192*G″+0.9505*B″

if (X/Xn)>0.008856
f(X/Xn)=(X/XN) ˆ (1/3)

else
f(X/Xn)=7.78*(X/Xn)+16/116

if (Y/Yn)>0.008856
f(Y/Yn)=(Y/Yn) ˆ (1/3)

else
f(Y/Yn)=7.78*(Y/Yn)+16/116

if (Z/Zn)>0.008856
f(Z/Zn)=(Z/Zn) ˆ (1/3)

else
f(Z/Zn)=7.78*(Z/Zn)+16/116

L*=116*f(Y/Yn)−16

a*=500*[f(X/Xn)−f(Y/Yn)]

b*=200*[f(Y/Yn)−f(Z/Zn)]

When absolute values of these values are at least equal to or less than 1, black is determined. There is available a method of determining black when a value of a square root of a sum of squares of the a* value, the b* value is at least equal to or less than 1.

The color component distributing section 6c receives the determination result Fa of the achromatic color determining section 6b, and distributes color components to one selected from the achromatic color K and the other colors C, M and Y by using the average value X₁ calculated by the color component average value calculating section 6a. In other words, based on the determination result Fa of the achromatic color determining section 6b, the color component distributing section 6c assigns a “1−average value X₁” value to K, and “0 values” to the other colors CMY if the determination result Fa indicates an achromatic color. If the determination result Fa does not indicate an achromatic color, the color component distributing section 6c assigns a “1−average value X₁” value to one of the predetermined color materials of C, M and Y, and “0” values to the other color materials including K.

A user setting section equipped with a mouse, a keyboard, a display and the like can be disposed in the color component distributing section 6c. The user setting section designates a color material to which a “1−average value X¹” value is assigned by user's operation.

The third color converting section 7 coverts the achromatic color among the color components into a mixed color of two colors including K and one of the other colors C, M and Y. FIG. 4 is a block diagram of the third color converting section 7. The third color converting section 7 converts bit image data of two colors into a synthesized color of two colors. The third color converting section 7 converts the achromatic color into a mixed color of two colors including K and one of the colors C, M and Y. FIG. 4 is a block diagram of the third color converting section 7. The third color converting section 7 includes a color component selecting section 7a, a black component generating section 7b, and a color component distributing section 7c.

The color component selecting section 7a outputs predetermined one of the color components RGB as a color component X₂. A user setting section equipped with a mouse, a keyboard, a display and the like can be disposed in the color component selecting section 7a. The user setting section designates a color component to be output as a color component X₂ by user's operation.

The black component generating section 7b calculates a black component K as gray based on luminance components of the color components RGB. A method of calculating the black component will be described. As for the calculation method of the black component K, there is a method which uses an equation indicated in NTSC Standard. In accordance with the NTSC Standard, luminance is represented by the following equation (1):
Luminance=0.3*R+0.59*G+0.11*B (1)
K can be calculated by using the luminance.

In accordance with another method, the color component G can be directly used as luminance if spectral sensitivity of a filter of the color component G is approximately equal to spectral luminous efficiency. Thus, the black component K is generated by the following equation (2):
K=(1−luminance)/2 (2)

The color component distributing section 7c assigns the color component X₂ output from the color component selecting section 7a to one of the colors C, M and Y other than black. In other words, the color component distributing section 7c assigns a “(1−X₂)/2” value to one of the predetermined color materials C, M and Y. The two color materials are divided into halves for the purpose of suppressing a total of color materials to 100% or less. For a ratio of the two color materials, a combination may be employed in which a total amount of these color materials is not greater than 100%. The black component can be prepared based on the average value of the color components RGB.

The selecting section 8 selects one of the conversion outputs of the first to third color converting sections 5 to 7 based on the switching signal Ca output from the print command translating section 4. That is, the selecting section 8 selects the conversion output of the first color converting section 5 if the switching signal Ca output from the print command translating section 4 indicates full-color printing. The selecting section 8 selects the conversion output of the second color converting section 6 if the switching signal Ca output from the print command translating section 4 indicates simple 2-color printing. The selecting section 8 selects the conversion output of the third color converting section 7 if the switching signal Ca output from the print command translating section 4 indicates natural image 2-color printing.

Next, an operation of the apparatus thus configured will be described.

The host computer 1 converts a printing output of a desired image into a format of a print command P, and issues the print command P to the image processing apparatus 2.

The image processing apparatus 2 receives the print command P issued from the host computer 1 to pass it to the print command translating section 4. The print command translating section 4 generates image data containing color components RGB from the print command P. The image data is sent to the first to third color converting sections 5 to 7.

The print command translating section 4 translates a pixel of the image data which is printed to be full-color printing, a character, a graph or a line drawing to be 2-color printing, or bit image printing of a natural image to be natural image 2-color printing from a page description language of the print command P, and outputs a switching signal Ca indicating a result of the translation.

The first color converting section 5 receives the color components RGB of the pixel of the image data generated by the print command translating section 4, and reads table values compliant with the color components RGB from the conversion table 5a. The first color converting section 5 performs interpolation calculation of the table values complaint with the color components RGB to obtain CMYK. Accordingly, the color components RGB are converted into full colors CMYK.

In the second color converting section 6, the color component average value calculating section 6a calculates an average value X₁ of the color components RGB.

The achromatic color determining section 6b determines an achromatic color based on equality of values of the color components RGB, and outputs a result Fa of the determination. In this case, the achromatic color determining section 6b determines the achromatic color if a difference between maximum and minimum values of the color components RGB is within a certain predetermined range.

That is, as long as RGB values can be within a range of “0 to 255”, black is determined when a difference between the maximum and minimum values of the input RGB is equal to or less than 1. A threshold value of the difference between the maximum and minimum values may be changed in accordance with an average value of the input RGB.

The black determination can also be made by converting the values of the RGB color components into CIELAB values. For example, when the input RGB are sRGB color space values to be set in the range of “0 to 255”, a a* value, a b* value can be obtained as follows:

R′=R/255

G′=G/255

B′=B/255

if R′, G′, B′<=0.04045
R″=R′/12.92
G″=G′/12.92
B″=B′/12.92

else
R″=[(R′+0.055)/1.055] ˆ2.4
G″=[(G′+0.055)/1.055] ˆ2.4
B″=[(B′+0.055)/1.055] ˆ2.4

X=0.4124*R″+0.3576*G″+0.1805*B″

Y=0.2126*R″+0.7152*G″+0.0722*B″

Z=0.0193*R″+0.1192*G″+0.9505*B″

if (X/Xn)>0.008856
f(X/Xn)=(X/XN) ˆ (1/3)

else
f(X/Xn)=7.78*(X/Xn)+16/116

if (Y/Yn)>0.008856
f(Y/Yn)=(Y/Yn) ˆ (1/3)

else
f(Y/Yn)=7.78*(Y/Yn)+16/116

if (Z/Zn)>0.008856
f(Z/Zn)=(Z/Zn) ˆ (1/3)

else
f(Z/Zn)=7.78*(Z/Zn)+16/116

L*=116*f(Y/Yn)−16

a*=500*[f(X/Xn)−f(Y/Yn)]

b*=200*[f(Y/Yn)−f(Z/Zn)]

When absolute values of these values are at least equal to or less than 1, black is determined. There is available a method of determining black when a value of a square root of a sum of squares of the a* value, the b* value is at least equal to or less than 1.

The color component distributing section 6c receives the determination result Fa of the achromatic color determining section 6b, and distributes color components to one selected from the achromatic color K and the other colors C, M and Y by using the average value X₁ calculated by the color component average value calculating section 6a. In other words, based on the determination result Fa of the achromatic color determining section 6b, the color component distributing section 6c assigns a “1−average value X₁” value to K, and “0 values” to the other colors CMY if the determination result Fa indicates an achromatic color. If the determination result Fa does not indicate an achromatic color, the color component distributing section 6c assigns a “1−average value X₁” value to one of the predetermined color materials of C, M and Y, and “0” values to the other color materials including K.

Accordingly, when the print command translating section 4 judges that the image data of the character, the graph or the line drawing should be printed by simple 2-color printing, the second color converting section 6 converts at least the image data of the character, the graph or the line drawing into two colors of K and another designated color, e.g., C. It may be converted into two colors of K and M or Y.

In the third color converting section 7, the color component selecting section 7a outputs predetermined one of the color components RGB as a color component X₂.

The black component generating section 7b calculates the equations (1) and (2) to obtain a black component K based on luminance components of the color components RGB.

The color component distributing section 7c assigns the color component X₂ output from the color component selecting section 7a to one of the colors C, M and Y other than black. In other words, the color component distributing section 7c assigns a “(1−X₂)/2” value to one of the predetermined color materials C, M and Y.

Accordingly, the achromatic color of the color components RGB is converted into a mixed color of two colors including K and one of the other colors C, M and Y by the third color converting section 7.

The selecting section 8 receives the switching signal Ca output from the print command translating section 4. The selecting section 8 selects the conversion output of the first color converting section 5 if the switching signal Ca output from the print command translating section 4 indicates full-color printing. The selecting section 8 selects the conversion output of the second color converting section 6 if the switching signal Ca output from the print command translating section 4 indicates simple 2-color printing. The selecting section 8 selects the conversion output of the third color converting section 7 if the switching signal Ca output from the print command translating section 4 indicates natural image 2-color printing.

One of the conversion outputs of the first to third color converting sections 5 to 7 selected by the selecting section 8 is sent to the printer 3. The printer 3 executes full-color printing, 2-color printing of a character, a graph or a line drawing, or 2-color printing of a bit image such as a natural image in an image forming medium based on color material amounts of CMYK.

Thus, according to the first embodiment, the color components RGB of the pixel of the image data are converted into the full colors CMYK to be output by the first color converting section 5, the pixel of the achromatic color in the image data is converted into the single K color by the second color converting section 6, the other colors are converted into one color to be output, the pixel of the achromatic color in the image data is converted into the mixed color of the two colors including K and another color to be output by the third color converting section 7, and one of the conversion outputs is selected by the selecting section 8.

Therefore, not only full-color printing is carried out but also, for example, a black character is printed by one color, e.g., black by the second color converting section 6, whereby a clear and beautiful printing result can be obtained. In this case, the line drawing is printed by another color to be as clear as the black character, whereby a beautiful printing result can be obtained.

A bit image such as a natural image can be output as a 2-color printing result having no sense of incompatibility in color tone by executing 2-color printing based on the conversion output of the third color converting section 7. This 2-color printing can print and output the image by two colors as if it is printed by full colors while only two colors are used. In the 2-color printing, the third color converting section 7 does not detect a hue or saturation. Accordingly, the third color converting section 7 can color-convert the bit image such as a natural image into a 2-color bit image at a high speed. As a result, a 2-color printing result can be obtained at a high speed.

Even when there is a mixture of full-color printing, 2-color printing of a character, a graph or a line drawing, and 2-color printing of a bit image such as a natural image executed in the same image forming medium, for example, by printing a black character by one color, e.g., K, it is possible to obtain a clear and beautiful 2-color printing result having no sense of incompatibility in color tone at a high speed.

Next, a second embodiment of the present invention will be described in detail with reference to the drawings. Portions similar to those of FIGS. 1 and 2 are denoted by similar reference numerals, and detailed description thereof will be omitted.

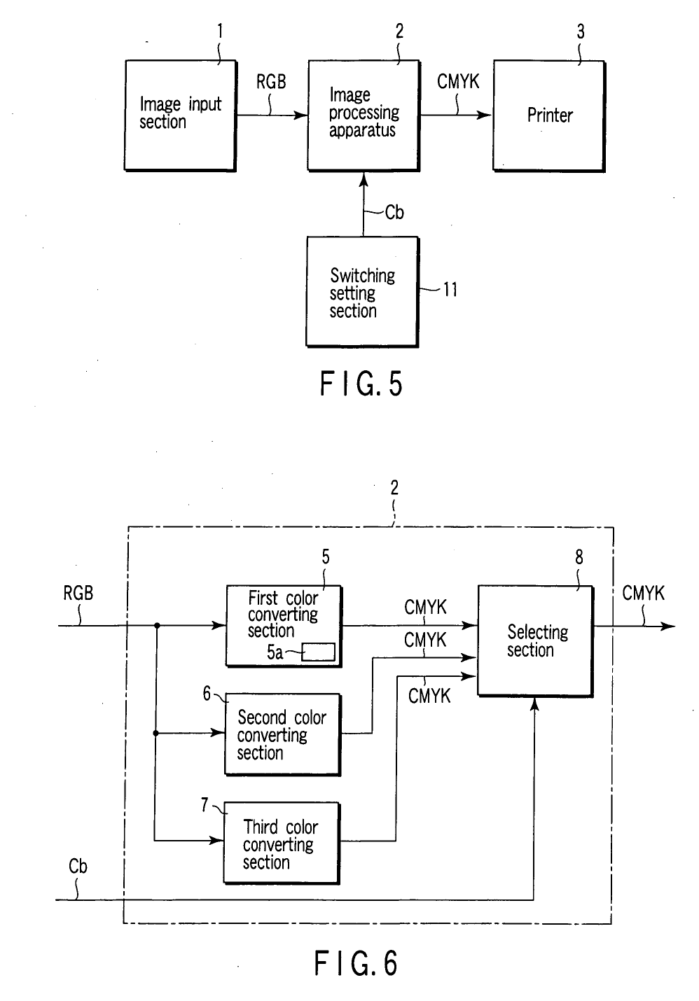

FIG. 5 is a block diagram of an image forming apparatus. The image forming apparatus includes an image input section 10, an image processing apparatus 2, a switching setting section 11, and a printer 3. The image input section 10 receives image data input from the outside, and sends the image data as color components RGB to the image processing apparatus 2.

The switching setting section 11 has a full-color conversion output mode, a simple 2-color conversion output mode, and a natural image 2-color conversion output mode. The switching setting section 11 outputs a switching signal Cb of one mode set from the outside by user's operation among the modes to a selecting section 8. For example, the switching setting section 11 includes an operation panel. The operation panel has operation switches or the like disposed thereon to select the modes.

FIG. 6 is a block diagram of the image processing apparatus 2. First to third color converting sections 5 to 7 are similar to those of the first embodiment.

A selecting section 8 selects one of the conversion outputs of the first to third color converting sections 5 to 7 based on a switching signal Cb output from a switching setting section 11. That is, the selecting section 8 selects the conversion output of the first color converting section 5 if the switching signal Cb output from the switching setting section 11 indicates full-color printing. The selecting section 8 selects the conversion output of the second color converting section 6 if the switching signal Cb output from the switching setting section 11 indicates simple 2-color printing. The selecting section 8 selects the conversion output of the third color converting section 7 if the switching signal Cb output from the switching setting 11 indicates natural image 2-color printing.

Next, an operation of the apparatus thus configured will be described.

The image input section 10 receives image data from the outside, and outputs the image data as color components RGB. The color components RGB are sent to the image processing apparatus 2.

The image processing apparatus 2 performs the same operation of that of the first embodiment in the first to third color converting sections 5 to 7. That is, the first color converting section 5 converts the color components RGB created by a print command translating section 4 into full colors CMYK. The second color converting section 6 converts the image data into two colors of K and another designated color, e.g., one of C, M and Y. In this case, the second color converting section 6 converts an achromatic color of the image data into K. The third color converting section 7 converts the achromatic color of the image data into a mixed color of two colors including K and one of C, M and Y.

The selecting section 8 receives the switching signal Cb output from the switching setting section 11. The selecting section 8 selects the conversion output of the first color converting section 5 if the switching signal Cb indicates full-color printing. The selecting section 8 selects the conversion output of the second color converting section 6 if the switching signal Cb output from the switching setting section 11 indicates simple 2-color printing. The selecting section 8 selects the conversion output of the third color converting section 7 if the switching signal Cb output from the switching setting section 11 indicates natural image 2-color printing.

The printer 3 executes full-color printing, 2-color printing of a character, a graph or a line drawing, or 2-color printing of a bit image such as a natural image in an image forming medium based on color material amounts of CMYK.

Thus, according to the second embodiment, by user's operation in the switching setting section 11, it is possible to select one of a full-color conversion output mode, a simple 2-color conversion output mode for printing image data of at least a character, a graph or a line drawing by two colors, and a natural image 2-color conversion output mode for printing and outputting 2-color bit image data. Thus, in addition to the effects of the first embodiment, it is possible to perform 2-color printing of a character, a graph or a line drawing or 2-color printing of a bit image such as a natural image at a high speed in accordance with user's request.

Next, a third embodiment of the present invention will be described in detail with reference to the drawings. Portions similar to those of FIG. 5 are denoted by similar reference numerals, and detailed description thereof will be omitted.

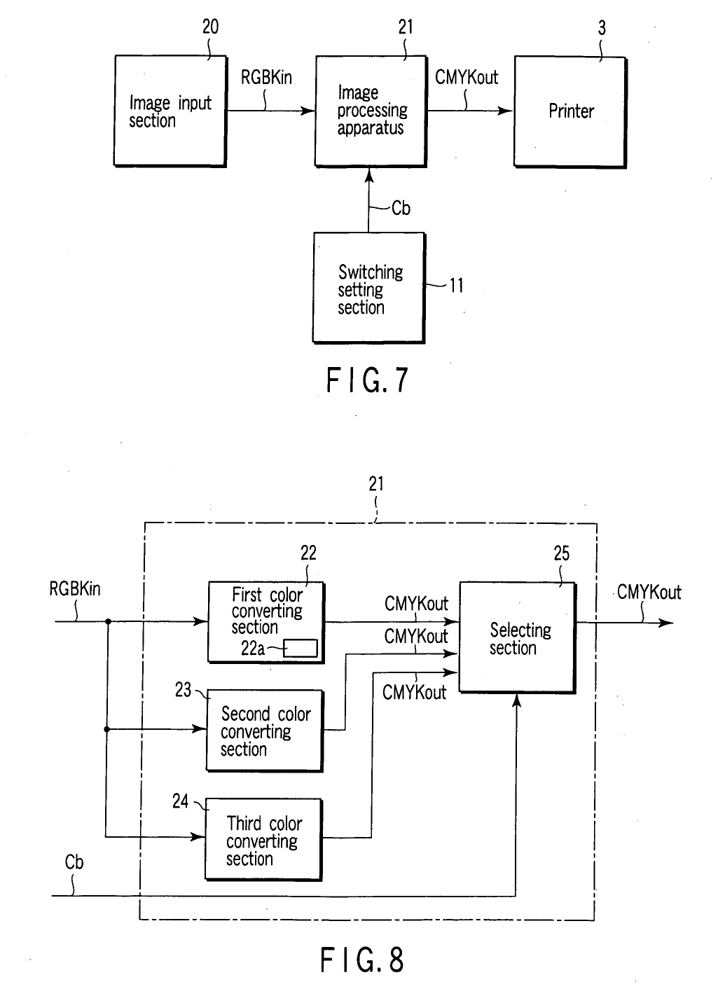

FIG. 7 is a block diagram of an image forming apparatus. The image forming apparatus includes an image input section 20, an image processing apparatus 21, a switching setting section 11, and a printer 3. For example, the image input section 20 includes an image reading device constituted of a 4-line CDD for reading RGBK of an image. The image input section 20 outputs RGBK of the read image as four color components of R, G, B, and Kin.

The image processing apparatus 21 performs image processing for receiving the four color components RGBKin output from the image input section 20 to convert them into color information of an image to be printed and output from the printer 3, i.e., color material amounts of CMYKin.

FIG. 8 is a block diagram of the image processing apparatus 21. The image processing apparatus 2 includes first to third color converting sections 22 to 24, and a selecting section 25.

The first color converting section 22 converts the four color components RGBKin output from the image input section 20 into full colors CMYKout. The first color converting section 22 has a table 22a for conversion from RGBKin into CMYK. In the conversion table 22a, table values are stored to convert RGBKin into CMYKout. The first color converting section 22 reads table values from the conversion table 22a in accordance with RGBKin, and performs interpolation calculation of the table values to obtain CMYKout.

The second color converting section 23 converts image data of at least a character, a graph or a line drawing into two colors: Kout and one designated color other than black, e.g., C, M or Y. The second color converting section 23 converts an achromatic color from the color components RGBKin into K. FIG. 9 is a block diagram of the second color converting section 23. The second color converting section 23 includes a color component average value calculating section 23a, an achromatic color determining section 23b, and a color component distributing section 23c.

The color component average value calculating section 23a calculates an average value X₃ of the color components RGB of the color components RGBKin.

The achromatic color determining section 23b determines K based on equality of values of the color components RGB of the color components RGBKin, and outputs a result Fb of the determination. However, considering inclusion of errors in the values of the color components RGB, the achromatic color determining section 23b determines an achromatic color if a difference between maximum and minimum values of the color components RGB is within a certain predetermined range.

The color component distributing section 23c receives the determination result Fb of the achromatic color determining section 23b, and distributes color components to one selected from Kout and the other colors C, M and Y by using the average value X₃ calculated by the color component average value calculating section 23a. In other words, based on the determination result Fb of the achromatic color determining section 23b, the color component distributing section 23c assigns kin to Kout, and “0 values” to the other colors CMY if the determination result Fb indicates an achromatic color. If the determination result Fb does not indicate an achromatic color, the color component distributing section 23c assigns a “1−average value X₃” value to one of the predetermined color materials of C, M and Y, and “0” values to the other color materials including Kout.

A user setting section equipped with a mouse, a keyboard, a display and the like can be disposed in the color component distributing section 23c. The user setting section designates a color material to which a “1−average value X₃” value is assigned by user's operation.

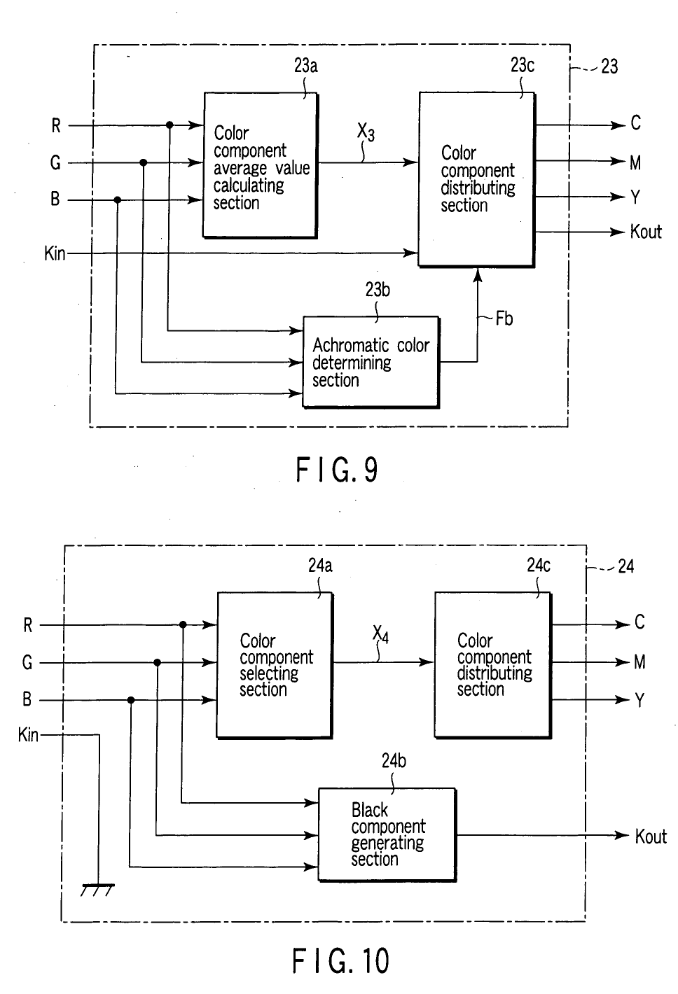

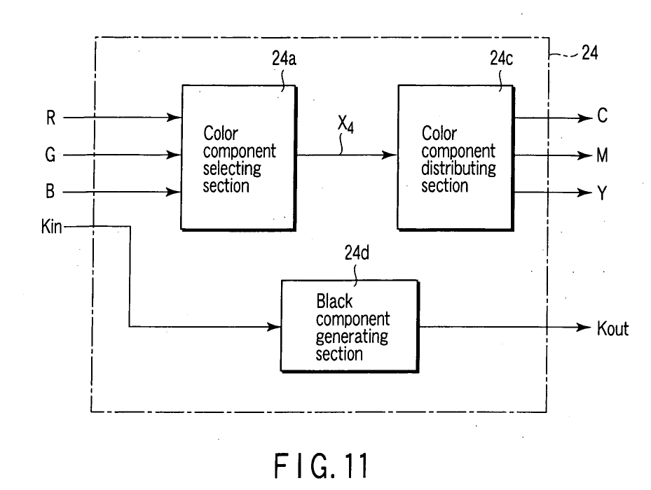

The third color converting section 24 coverts a pixel of the achromatic color of the image data into a mixed color of two colors including Kout and one of the other colors C, M and Y. The third color converting section 24 converts bit image data of two colors into a synthesized color of two colors. The third color converting section 24 converts the achromatic color into a mixed color of two colors including Kout and one of the colors C, M and Y. FIG. 10 is a block diagram of the third color converting section 24. The third color converting section 24 includes a color component selecting section 24a, a black component generating section 24b, and a color component distributing section 24c.

The color component selecting section 24a outputs the color components RGB of the color components RGBKin as a predetermined color component X₄. A user setting section equipped with a mouse, a keyboard, a display and the like can be disposed in the color component selecting section 24a. The user setting section designates a color component to be output as a color component X₄ by user's operation.

The black component generating section 24b calculates a black component Kout based on luminance components of the color components RGB of the color components RGBKin. A method of calculating the black component Kout will be described. The calculation method of the black component Kout is indicated in NTSC Standard. In accordance with the NTSC Standard, luminance is represented by the following equation (3):
Luminance=0.3*R+0.59*G+0.11*B (3)
K can be calculated by using the luminance.

In accordance with another method, the color component G can be directly used as luminance if spectral sensitivity of a filter of the color component G is approximately equal to spectral luminous efficiency. Thus, the black component Kout is generated by the following equation (4):
Kout=(1−luminance)/2 (4)

The color component distributing section 24c assigns the color component X₄ output from the color component selecting section 24a to one of the colors C, M and Y other than Kout. In other words, the color component distributing section 24c assigns a “(1−X₄)/2” value to one of the predetermined color materials C, M and Y. The two color materials are divided into halves for the purpose of suppressing a total of color materials to 100% or less. For a ratio of the two color materials, a combination may be employed in which a total amount of these color materials is not greater than 100%. The black component can be prepared based on an average value of the color components RGB.

The selecting section 25 receives the switching signal Cb output from the switching setting section 11, and selects one of the conversion outputs of the first to third color converting sections 22 to 24 based on the switching signal Cb. That is, the selecting section 25 selects the conversion output of the first color converting section 22 if the switching signal Cb indicates full-color printing. The selecting section 25 selects the conversion output of the second color converting section 23 if the switching signal Cb indicates simple 2-color printing of a character, a graph or a line drawing. The selecting section 25 selects the conversion output of the third color converting section 24 if the switching signal Cb indicates natural image 2-color printing of a bit image such as a natural image.

Next, an operation of the apparatus thus configured will be described.

The image input section 10 reads RGBK of an image by, e.g., a 4-line CDD, and outputs the RGBK of the read image as four color components of RGBKin.

The image processing apparatus 21 receives the four color components RGBKin from the image input section 20, and sends the four color components RGBKin to the first to third color converting sections 22 to 24.

The first color converting section 22 receives the color components RGBKin from the image input section 20, and reads table values compliant with the color components RGBKin from the conversion table 22a. The first color converting section 22 performs interpolation calculation of the table values compliant with the color components RGBKin to obtain CMYKout. Hence, the color components RGBKin are converted into full colors CMYKout.

In the second color converting section 23, the color component average value calculating section 23a calculates an average value X₃ of the color components RGB.

The achromatic color determining section 23b determines an achromatic color based on equality of values of the color components RGB, and outputs a result Fb of the determination. In this case, the achromatic color determining section 23b determines the achromatic color if a difference between maximum and minimum values of the color components RGB is within a certain predetermined range.

Upon reception of the determination result Fb of the achromatic color determining section 23b, the color component distributing section 23c distributes color components to one selected from Kout and other colors C, M and Y by using the average value X₃ calculated by the color component average value calculating section 23a. That is, based on the determination result Fb of the achromatic color determining section 23b, the color component distributing section 23c assigns Kin to Kout if the determination result Fb indicates an achromatic color, and “0” values to the other colors. If the determination result Fb indicates a color other than an achromatic color, the color component distributing section 23c distributes “1−average value X₃” value to predetermined one of the color materials C, M and Y, and “0” values to the other color materials including Kout.

Accordingly, the image data of at least a character, a graph or a line drawing is converted into two colors of Kout and another designated color, e.g., cyan C by the second color converting section 23. The image may be converted into two colors of Kout and M or Y.

In the third color converting section 24, the color component selecting section 24a outputs the color components RGB as predetermined color components X₄.

The black component generating section 24b calculates the equations (3) and (4) to obtain a black component Kout based on luminance components of the color components RGB.

The color component distributing section 24c assigns the color component X₄ output from the color component selecting section 24a to one of the colors C, M and Y other than Kout. In other words, the color component distributing section 24c assigns a “(1−X₄)/2” value to one of the predetermined color materials C, M and Y.

Accordingly, the achromatic color of the color components RGBKin is converted into a mixed color of two colors including Kout and one of the other colors C, M and Y by the third color converting section 24.

The selecting section 25 receives the switching signal Cb output from the switching setting section 11. The selecting section 25 selects the conversion output of the first color converting section 22 if the switching signal Cb indicates full-color printing. The selecting section 25 selects the conversion output of the second color converting section 23 if the switching signal Cb indicates simple 2-color printing of a character, a graph or a line drawing. The selecting section 25 selects the conversion output of the third color converting section 24 if the switching signal Cb indicates printing of a bit image such as a natural image.

One of the conversion outputs of the first to third color converting sections 22 to 24 selected by the selecting section 25 is sent to the printer 3. The printer 3 executes full-color printing, simple 2-color printing of a character, a graph or a line drawing, or 2-color printing of a bit image such as a natural image in an image forming medium based on color material amounts of CMYK.

Thus, according to the third embodiment, RGBK of the image read by, e.g., the 4-line CDD are output as four color components of RGBKin by the image input section 20, the color components RGBKin are converted into the full colors CMYKout to be output by the first color converting section 22, the achromatic color is converted from the color components RGB into K by the second color converting section 23, the achromatic color of the color components RGB is converted into the mixed color of the two colors including K and another color to be output by the third color converting section 24, and one of the conversion outputs is selected by the selecting section 25.

Therefore, even in the case of the four color components RGBKin read by the image input section 20 equipped with, e.g., the 4-line CDD, not only full-color printing is carried out but also, for example, a black character is printed by one color, e.g., black by the second color converting section 23, whereby a clear and beautiful printing result can be obtained. In this case, the line drawing is printed by another color to be as clear as the black character, whereby a beautiful printing result can be obtained.

A bit image such as a natural image can be output as a 2-color printing result having no sense of incompatibility in color tone by executing 2-color printing based on the conversion output of the third color converting section 24. The third color converting section 24 does not detect a hue or saturation. Accordingly, the third color converting section 24 can color-convert the bit image such as a natural image into a 2-color bit image at a high speed.

Even when there is a mixture of full-color printing, 2-color printing of a character, a graph or a line drawing, and 2-color printing of a bit image such as a natural image executed in the same image forming medium, for example, by printing a black character by one color, e.g., black, it is possible to obtain a clear and beautiful 2-color printing result having no sense of incompatibility in color tone at a high speed.

The third color converting section 24 of the third embodiment can be modified as follows.

FIG. 11 is a block diagram of a third color converting section 24 when spectral sensitivity of a color component filter of Kin is approximately equal to spectral luminous efficiency. The black component generating section 24d outputs Kin of four color components RGBKin directly as Kout. In other words, the black component generating section 24d generates a black component by the following equation (5)
Kout=(1−Y)/1 (5)

The present invention is not limited to the embodiments, but it can be modified as follows.

Each embodiment can be applied not only to the full-color printing, the 2-color printing of a character, a graph, or a line drawing and the printing of a bit image such as a natural image but also to 2-color printing of image data of a painting, a photograph or the like.

The 2-color printing is not limited to the two colors of K and one of C, M and Y, but it can be applied to a combination of various colors such as a combination of two colors of C and one of K, M and Y.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An image processing apparatus comprising:
a first color converting section which converts image data constituted of a plurality of color components into full colors;
a second color converting section which converts an achromatic color of the image data constituted of the plurality of color components into a black color only;
a third color converting section which converts the achromatic color of the image data constituted of the plurality of color components into a mixed color of two colors including black and another color; and
a selecting section which selects one from conversion outputs of the first to third color converting sections.

2. The image processing apparatus according to claim 1, further comprising a switching section which outputs a switching signal to the selecting section to switch to one of the conversion outputs of the first to third color converting sections.

3. The image processing apparatus according to claim 1, wherein:
the color components include red, green and blue;
the full colors include cyan, magenta, yellow and black, and
the first color converting section converts the red, the green and the blue into the cyan, the magenta, the yellow and the black.

4. The image processing apparatus according to claim 1, wherein the second color converting section converts image data of at least a character or a line drawing into two colors of the black and the designated color.

5. The image processing apparatus according to claim 1, wherein:
the color components include red, green and blue; and
the second color converting section converts an achromatic color into black, and the red, the green and the blue into one color of the designated cyan, magenta and yellow.

6. The image processing apparatus according to claim 1, wherein the second color converting section comprises:
a color component average value calculating section which calculates an average value of the plurality of color components;
an achromatic color determining section which determines an achromatic color based on equality of values of the plurality of color components; and
a color component distributing section which receives a determination result of the achromatic color determining section and distributes color components to the achromatic color or the other colors based on the average value calculated by the color component average value calculating section.

7. The image processing apparatus according to claim 1, wherein the second color converting section comprises:
a color component average value calculating section which calculates an average value of the plurality of color components;
an achromatic color determining section which determines a color having a value of each of the plurality of color components set in a range of at least −1≦a*≦1, −1≦b*≦1 in CIELAB value as an achromatic color; and
a color component distributing section which receives a determination result of the achromatic color determining section and distributes color components to the achromatic color or the other colors based on the average value calculated by the color component average value calculating section.

8. The image processing apparatus according to claim 1, wherein the third color converting section converts bit image data of at least two colors into a synthesized color of the two colors.

9. The image processing apparatus according to claim 1, wherein:
the color components include red, green and blue; and
the third color converting section converts the achromatic color into a mixed color of two colors including black and at least one selected from the cyan, the magenta and the yellow.

10. The image processing apparatus according to claim 1, wherein the third color converting section comprises:
a color component selecting section which outputs the color components as predetermined color components;
a black component generating section which generates black based on luminance components from the color components; and
a color component distributing section which assigns the color components output from the color component selecting section to one color other than the black.

11. The image processing apparatus according to claim 2, wherein the switching section comprises a print command translating section which generates the color components from a print command, translates the full colors, the image data of at least a character or a line drawing, or bit image data of two colors from information written in the print command, and outputs a switching signal to the selecting section based on a result of the translation.

12. The image processing apparatus according to claim 2, wherein the switching section comprises a switching setting section which has a mode of converting and outputting the full colors, a mode of converting and outputting the image data of at least a character or a line drawing, and a mode of converting and outputting bit image data of two colors, and outputs a switching signal of one of the modes set by an external operation to the selecting section.

13. An image processing apparatus comprising:
a first color converting section which converts image data constituted of four color components of red, green, blue and black into full colors;
a second color converting section which converts an achromatic color of the image data constituted of the four color components into black;
a third color converting section which converts the achromatic color of the image data constituted of the four color components into a mixed color of two colors including black and one selected from cyan, magenta and yellow; and
a selecting section which selects one from conversion outputs of the first to third color converting sections.

14. The image processing apparatus according to claim 13, further comprising a switching setting section which has a mode of switching to the conversion output of the first color converting section, a mode of switching to the conversion output of the second color converting section, and a mode of switching to the conversion output of the third color converting section, and outputs a switching signal of one of the modes set by an external operation to the selecting section.

15. The image processing apparatus according to claim 13, wherein the second color converting section converts image data of at least a character or a line drawing into two colors of the black and the designated color.

16. The image processing apparatus according to claim 13, wherein the second color converting section comprises:
a color component average value calculating section which calculates an average value of the color components of the red, the green and the blue;
an achromatic color determining section which determines the black based on equality of values of the color components of the red, the green and the blue; and
a color component distributing section which receives a determination result of the achromatic color determining section and the color component of the black, and distributes color components to the cyan, the magenta or the yellow including the black based on the average value calculated by the color component average value calculating section.

17. The image processing apparatus according to claim 13, wherein the third color converting section converts bit image data of at least two colors into a synthesized color of the two colors.

18. The image processing apparatus according to claim 13, wherein the third color converting section comprises:
a color component selecting section which outputs the color components of the red, the green and the blue as predetermined color components;
a black component generating section which generates black based on luminance components from the color components of the red, the green and the blue; and
a color component distributing section which assigns the color components output from the color component selecting section to one color other than the black.

19. The image processing apparatus according to claim 13, wherein the third color converting section comprises:
a color component selecting section which outputs the color components of the red, the green and the blue as predetermined color components;
a black component generating section which directly outputs the black of the four color components; and
a color component distributing section which assigns the color components output from the color component selecting section to one color other than the black.

20. An image forming apparatus comprising:
a computer which issues a print command;
an image processing apparatus which receives the print command from the computer to convert the print command into color information of an image to be printed and output; and
a printer which prints and outputs the image based on the color information converted by the image processing apparatus,
wherein the image processing apparatus comprises:
a print command translating section which generates a plurality of color components from the print command, translates printing contents based on information written in the print command, and outputs a switching signal based on a result of the translation;
a first color converting section which converts the plurality of color components into full colors;
a second color converting section which converts an achromatic color among the plurality of color components into black;
a third color converting section which converts the achromatic color among the plurality of color components into a mixed color of two colors including black and another color; and
a selecting section which selects one from conversion outputs of the first to third color converting sections based on the switching signal output from the print command translating section.

21. An image forming apparatus comprising:
an image input section which receives an image and outputs the image as one constituted of a plurality of color components;
an image processing apparatus which receives the plurality of color components from the image input section to convert the plurality of color components into color information of the image to be printed and output; and
a printer which prints and outputs the image based on the color information converted by the image processing apparatus,
wherein the image processing apparatus comprises:
a print command translating section which generates a plurality of color components from the print command, translates printing contents from information written in the print command, and outputs a switching signal based on a result of the translation;
a first color converting section which converts the plurality of color components into full colors;
a second color converting section which converts an achromatic color among the plurality of color components into black;
a third color converting section which converts the achromatic color among the plurality of color components into a mixed color of two colors including black and another color; and
a selecting section which selects one from conversion outputs of the first to third color converting sections based on the switching signal output from the print command translating section.

22. A method of processing an image, comprising:
converting a plurality of color components into full colors to output the same;
converting an achromatic color among the plurality of color components into black to output the same;
converting the achromatic color among the plurality of color components into a mixed color of two colors including black and another color to output the same; and
selecting one of the conversion outputs.
